(19) United States
(12) Patent Application Publication
(10) Pub. No.: US 2025/0355583 A1
(43) Pub. Date: Nov. 20, 2025

(54) DYNAMIC WRITE BOOSTER DISABLEMENT

(71) Applicant: Micron Technology, Inc., Boise, ID (US)

(72) Inventors: Yuda Qian, Shanghai (CN); Hong Lu, San Jose, CA (US); Xing Wang, Shanghai (CN); Qingyuan Wang, Shanghai (CN)

(21) Appl. No.: 19/205,761

(22) Filed: May 12, 2025

Related U.S. Application Data
(60) Provisional application No. 63/649,899, filed on May 20, 2024.

(51) Int. Cl. G06F 3/06

(52) U.S. Cl. CPC G06F 3/0634; G06F 3/0619; G06F 3/0631; G06F 3/0673

(57) ABSTRACT

Methods, systems, and devices for dynamic write booster disablement are described. A memory system may determine whether a quantity of data stored to the memory system satisfies a first threshold value. In some examples, a block of memory cells of the memory system may be allocated to a write booster cursor. The memory system may disable operation of a write booster mode in response to determining that the quantity of data satisfies the first threshold value. As such, the memory system may allocate the block of memory cells of the write booster cursor to store data in response to disabling the operation of the write booster mode. If the quantity of data satisfies a second threshold value, the memory system may determine to open a second write booster cursor and allocate a second block of memory cells to the second write booster cursor.

### CROSS REFERENCE

The present application for patent claims priority to U.S. Patent Application No. 63/649,899 by Qian et al., entitled “DYNAMIC WRITE BOOSTER DISABLEMENT,” filed May 20, 2024, which is assigned to the assignee hereof, and which is expressly incorporated by reference in its entirety herein.

### TECHNICAL FIELD

The following relates to one or more systems for memory, including dynamic write booster disablement.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 shows an example of a system that supports dynamic write booster disablement in accordance with examples as disclosed herein.

FIG. 2 shows an example of a system that supports dynamic write booster disablement in accordance with examples as disclosed herein.

FIGS. 3-5 each show an example of a process that supports dynamic write booster disablement in accordance with examples as disclosed herein.

FIG. 6 shows a block diagram of a memory system that supports dynamic write booster disablement in accordance with examples as disclosed herein.

FIG. 7 shows a flowchart illustrating a method or methods that support dynamic write booster disablement in accordance with examples as disclosed herein.

### DETAILED DESCRIPTION

Some memory systems may include or otherwise support a write booster mode of operation. The write booster mode may allow the memory system to write information (e.g., data) relatively faster than a normal mode of operation (e.g., a non-write booster mode). If the write booster mode is enabled, the memory system may write data to one or more single-level cells (SLCs), and then move (e.g., write, fold) the data to one or more triple-level cells (TLCs) at a later time (e.g., as part of a background operation, a maintenance operation, or garbage collection operation). In some cases, the SLC portion of memory may be an example of an SLC block of memory cells associated with a write booster cursor. In some examples, a cursor may be a logical partition of memory associated with memory cells that may be read from or written to. As such, a write booster cursor may be a logical partition of physical cells that are designated for use in performing operations of the write booster mode. During the normal mode of operation, the memory system may write data directly into the TLC portion of memory which may take more time than writing the data to the SLC portion of memory.

In some examples, as the quantity of data stored to the memory system increases, the memory system may refrain from operating in accordance with the write booster mode. For instance, if a relatively large quantity of data is stored to the memory system (e.g., if the quantity of stored data is above a given threshold), the memory system may not have enough unused (e.g., free) blocks of memory cells to write data using the write booster mode. In some examples, the quantity of data stored to a memory device may be associated or otherwise referred to as its logical saturation. Thus, such large quantities of data stored to the memory system may be associated with a high level of logical saturation, and the memory system may refrain from writing data using the write booster mode. As such, the SLC block allocated to the write booster cursor may remain unused during high levels of logical saturation, which may reduce the effective storage capacity of the memory system.

A memory system configured to dynamically disable a write booster mode of operation and allocate the associated block of memory cells for another use, which may improve the overall storage capacity of the memory system, is described herein. For example, the memory system may determine whether a quantity of data stored to the memory system satisfies a first threshold value. If the quantity of data satisfies (e.g., exceeds, is greater than or equal to) the first threshold value, the memory system may disable the write booster mode. For instance, the memory system may close the write booster cursor and allocate the SLC block used by the write booster cursor for other operations (e.g., non-write-booster operations).

In response to allocating the SLC block for other operations, the memory system may close the write booster cursor and disable operations of the write booster mode. If, however, the level of logical saturation at the memory system were to reduce, the memory system may determine to re-enable operation of the write booster mode. For example, if the memory system determines (e.g., after closing the write booster cursor) that the quantity of data stored to the memory system satisfies (e.g., is less than or equal to) a second threshold value, the memory system may open a second write booster cursor, allocate a second SLC block to the second write booster cursor, and enable operations of the write booster mode. By dynamically allocating an SLC block (or multiple SLC blocks) for use in a write booster mode and for storing data (e.g., as part of a non-write-booster mode of operation), the memory system may increase the utilization of memory storage resources. As such, the memory system may increase data storage capacity during high levels of logical saturation while maintaining the performance increase associated with the write booster mode during lower levels of logical saturation.

In addition to applicability in memory systems as described herein, techniques for dynamic write booster disablement may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing memory storage capacity, which may increase storage longevity of the memory system, among other benefits.

Features of the disclosure are illustrated and described in the context of systems, devices, and circuits. Features of the disclosure are further illustrated and described in the context of processes and flowcharts.

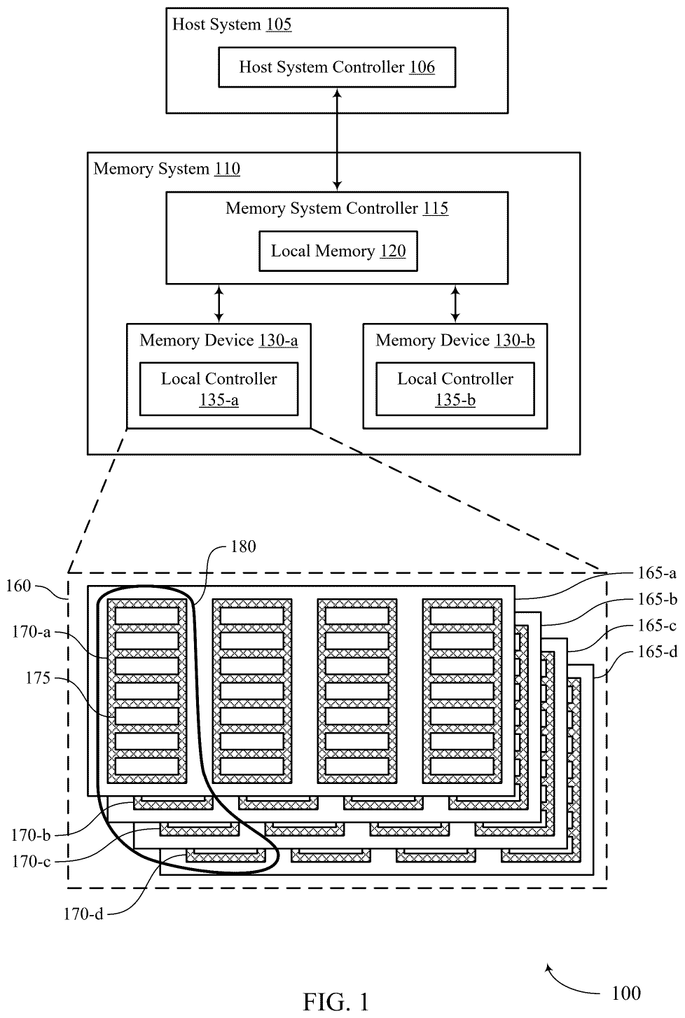

FIG. 1 shows an example of a system 100 that supports dynamic write booster disablement in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as SLCs. Additionally, or alternatively, a NAND memory device 130 may include memory cells configured to each store multiple bits of information, which may be referred to as multi-level cells (MLCs) if configured to each store two bits of information, as TLCs if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some examples, the memory system 110 may be configured to dynamically disable a write booster mode of operation and allocate the associated block 170 of memory cells to improve the overall storage capacity of the memory system 110. For example, the memory system 110 may determine whether a quantity of data stored to the memory system 110 satisfies a first threshold value. If the quantity of data satisfies (e.g., exceeds, is greater than or equal to) the first threshold value, the memory system 110 may disable the write booster mode. For instance, the memory system 110 may close the write booster cursor and allocate the SLC block 170 used by the write booster cursor to be used as data storage at the memory system 110 (e.g., data storage for a non-write-booster mode of operation).

In response to allocating the SLC block 170 to store data (e.g., as part of a non-write-booster mode of operation), the memory system 110 may close the write booster cursor and disable operations of the write booster mode. If, however, the level of logical saturation at the memory system 110 were to reduce, the memory system 110 may determine to re-enable operation of the write booster mode. For example, if the memory system 110 determines (e.g., after closing the write booster cursor) that the quantity of data stored to the memory system 110 satisfies (e.g., is less than or equal to) a second threshold value, the memory system 110 may open a second write booster cursor, allocate a second SLC block 170 to the second write booster cursor, and enable operations of the write booster mode. By dynamically allocating an SLC block 170 (or multiple SLC blocks 170) for use in a write booster mode and for storing data, the memory system 110 may increase the utilization of memory storage resources. As such, the memory system 110 may increase data storage capacity during high levels of logical saturation while maintaining the performance increase associated with the write booster mode during lower levels of logical saturation.

The system 100 may include any quantity of non-transitory computer readable media that support dynamic write booster disablement. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

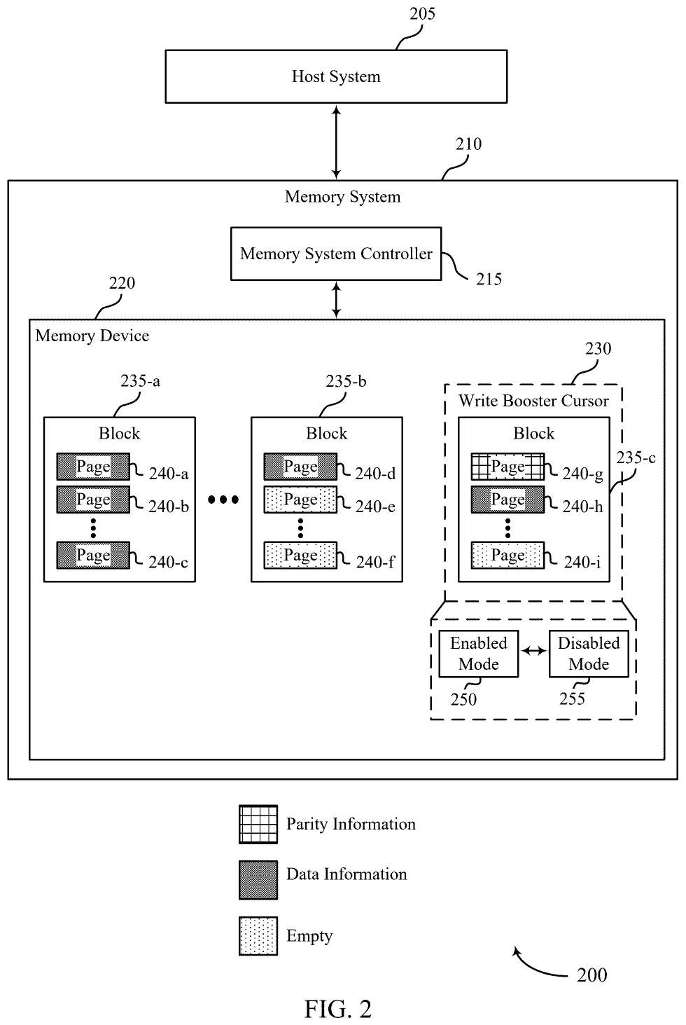

FIG. 2 shows an example of a system 200 that supports dynamic write booster disablement in accordance with examples as disclosed herein. The system 200 may include a host system 205 and a memory system 210. In some instances, the memory system 210 may include a memory system controller 215 and a memory device 220, which may be examples of the corresponding devices described with respect to FIG. 1. In some examples, the memory system controller 215 may be configured to dynamically disable a write booster mode of operation and allocate an associated block of memory cells to improve the overall storage capacity of the memory system 210.

As illustrated in FIG. 2, the memory device 220 may include a set of blocks 235 (e.g., block 235-a, 235-b, and 235-c). In some examples, the memory device 220 may be a NAND device (e.g., NAND flash device), such that each block 235 may include a set of memory cells. For instance, each block 235 may include a respective set of pages 240, and each page 240 may include a set of memory cells. As illustrated in FIG. 2, block 235-a may include a first respective set of pages 240 (e.g., page 240-a, 240-b, and 240-c), block 235-b may include a second respective set of pages 240 (e.g., page 240-d, 240-e, and 240-f), and block 235-c may include a third respective set of pages 240 (e.g., page 240-g, 240-h, and 240-i). While FIG. 2 illustrates three blocks 235, it is understood that the memory device 220 may include any quantity of blocks 235 where each block 235 includes any quantity of pages 240.

In some examples, block 235-a and block 235-b may be an example of a portion of memory that includes multiple level cells. The multiple level cells may include multi-level cells (e.g., MLCs) configured to store two bits of data, triple-level cells (e.g., TLCs) configured to store three bits of data, or quad-level cells (e.g., QLCs) configured to store four bits of data. Additionally, or alternatively, the block 235-c may be an example of a portion of memory that includes single level cells (e.g., SLCs) configured to store one bit of data per memory cell. In some examples, SLC portions of memory may be associated with faster writing speeds compared to MLC, TLC, or QLC portions of memory.

As illustrated in FIG. 2, block 235-c may be associated with a write booster cursor 230 used for performing operations associated with a write booster mode. For instance, the write booster mode may allow the memory system controller 215 to write information faster than a normal mode (e.g., a non-write-booster mode). During the write booster mode, the memory system controller 215 may write data to the block 235-c associated with the write booster cursor 230. Based on the block 235-c being an SLC portion of memory (e.g., based on the associated memory cells being operated as SLCs), the memory system controller 215 may write data to the write booster cursor 230 at a faster rate compared to directly writing data to a TLC or QLC. At a later time (e.g., as part of a background operation), the memory system controller 215 may transfer the data from the block 235-c to a TLC or QLC portion of memory (e.g., transfer to block 235-a or 235-b). By operating in accordance with the write booster mode, the memory system controller 215 may increase writing performance of the system 200.

In some examples, the memory system 210 may operate in accordance with a protection scheme (e.g., a redundant array of independent NAND (RAIN) protection scheme) for data retention purposes. For example, the memory system 210 may perform a set of logical operations (e.g., exclusive OR (XOR) operations) on a set of data to be stored to the memory device 220 to generate parity information associated with the set of data. Thus, the memory system 210 may detect, and in some cases correct, errors in the set of data using the parity information associated with the set of data. As illustrated in FIG. 2, the block 235-c may be configured to store data to one or more pages 240 (e.g., pages 240-h through 24h-i). Additionally, or alternatively, parity information associated with the data information stored at the block 235-c may be generated and stored to a portion of the memory device 220. As such, in response to the block 235-c being full with data information, the memory system controller 215 may flush (e.g., write) the generated parity information to the end of the block 235-c. In other examples (not shown) parity information may be stored with respective data (e.g., to pages 240-h through 240-i).

In some examples, the memory system controller 215 may write data to the blocks 235 of the memory device 220 (e.g., during a write booster mode or a normal mode). For instance, the memory system controller 215 may receive (e.g., from the host system 205) one or more access operations for writing data to the memory device 220. As such, the memory system controller 215 may write bits of data to the memory cells associated with the pages 240. As illustrated in FIG. 2, one or more of the pages 240 may be filled with data information. Additionally, or alternatively, one or more of the pages 240 may be empty or partially filled with data information.

In some examples, an empty page 240 may currently store no data or may include data that has been flagged for erasing (e.g., data that may be overwritten). In some examples, the quantity of data stored to the memory device 220 may be associated with a level of logical saturation, a level of physical saturation, or both. In some examples, logical saturation may refer to a level of logical address space of the memory device 220 that is utilized to store data. For instance, the level of logical saturation of the memory device 220 may increase as a quantity of logical addresses associated with stored data increases.

In some examples, physical saturation may refer to the exhaustion of physical memory resources in the memory device 220. As such, a level of physical saturation may increase as the quantity of utilized physical memory of the memory device 220 increases. That is, logical saturation may be associated with the utilization of logical address space, while physical saturation may be associated with the utilization of physical addresses (e.g., physical address space). In some examples of the techniques described herein, the quantity of data stored to the memory device 220 may reference logical saturation; however, it is understood that the quantity of data stored to the memory device 220 may also correspond to physical saturation.

In some cases, the memory system 210 may refrain from operating in accordance with the write booster mode in cases of high logical saturation, high physical saturation, or both. For instance, if the quantity of data information stored to the memory device 220 satisfies (e.g., exceeds, is greater than or equal to) a given threshold quantity of data, the memory system controller 215 may refrain from writing data using the write booster mode. As such, the block 235-c may be able to be allocated for a different use in response to the memory system controller 215 refraining from using the write booster mode at high levels of physical or logical saturation. As such, it may be advantageous to allocate the block 235-c for operations other than the write booster mode if the memory device 220 is associated with a high level of logical saturation.

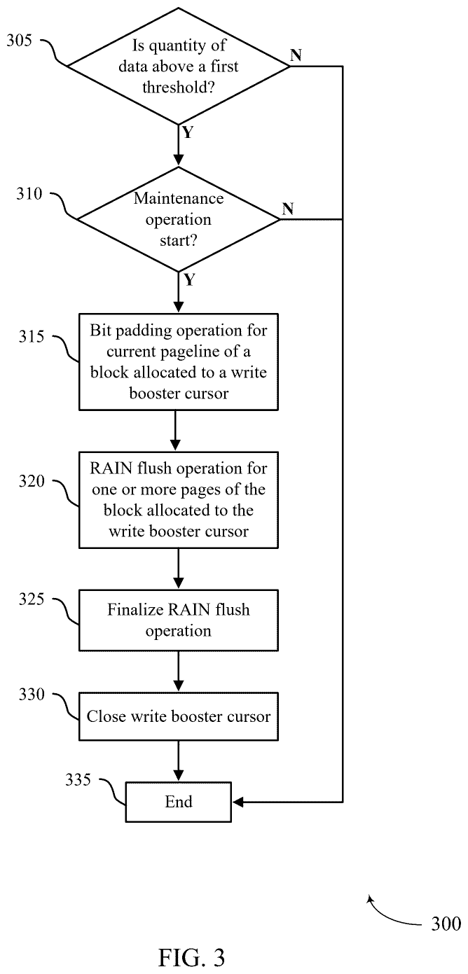

According to the techniques described herein, the memory system controller 215 may determine to dynamically disable a write booster mode of operation and allocate the associated block 235-c to improve the overall storage capacity of the memory system 210. For example, the memory system 210 may determine whether a quantity of data stored to the memory device 220 satisfies (e.g., exceeds, is greater than or equal to) a first threshold value. If the memory system 210 determines that the quantity of data satisfies the first threshold value, then the memory system 210 may transition the write booster mode from an enabled mode 250 to a disabled mode 255 (e.g., the memory system controller 215 may disable the write booster mode). For example, the memory system controller 215 may allocate the block 235-c for use in storing data associated with a non-write-booster mode of operation. In some examples, the memory system controller 215 may reallocate the block 235-c while preserving RAIN parity information stored to the block 235-c, as described herein with reference to FIG. 3. For instance, if the memory system controller 215 determines to close (e.g., force close) the write booster cursor 230, and if the block 235-c is not fully written to (e.g., full), then parity information associated with the data of block 235-c may be written to the currently free pageline of the block 235-c (e.g., without writing dummy bits to the end of the block 235-c). As such, the memory system controller 215 may directly close the write booster cursor 230 when one or more conditions are met, as discussed in FIG. 3. In some instances, the memory cells of block 235-c may be operated as MLCs, TLCs, or QLCs in a non-write-booster mode of operation.

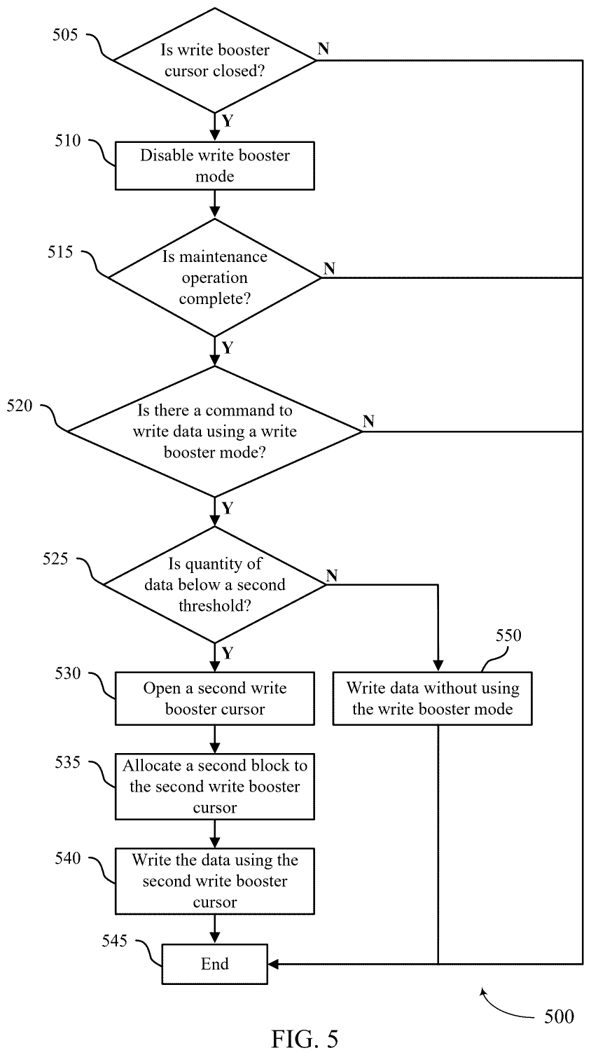

In response to reallocating the block 235-c, the memory system 210 may close the write booster cursor 230 and transition the write booster mode from the enabled mode 250 to the disabled mode 255. As such, the memory system controller 215 may refrain from operating in accordance with the write booster mode. If, however, the level of logical saturation at the memory device 220 were to reduce, the memory system controller 215 may determine to enable operation of the write booster mode. For example, if the memory system controller 215 determines (e.g., after closing the write booster cursor 230) that the quantity of data stored to the memory device 220 satisfies a second threshold (e.g., below, less than or equal to), then the memory system controller 215 may determine to open a second write booster cursor 230, allocate a second virtual block 235 to the second write booster cursor 230, and transition the write booster mode from the disabled mode 255 to the enabled mode 250. In some examples, the second threshold value may be less than the first threshold value. Discussions of the memory system 210 opening a second write booster cursor 230 are described herein, including with reference to FIG. 5.

Dynamically allocating a block 235-c between use for the write booster mode and a non-write-booster mode may increase the utilization of memory storage resources at the memory system 210. As such, the system 200 may increase the data storage capacity of the memory system 210 during high levels of logical saturation (e.g., data quantity above the first threshold value) while maintaining performance increase associated with the write booster mode during lower levels of logical saturation (e.g., data quantity below the second threshold value).

FIG. 3 shows an example of a process 300 that supports dynamic write booster disablement in accordance with examples as disclosed herein. In some examples, the process may be implemented by one or more aspects of systems 100 and 200. For instance, the process 300 may be implemented by a memory system 110 or 210 described with reference to FIGS. 1 and 2, respectively. In some examples, process 300 may correspond to one or more operations performed by the memory system to dynamically allocate a block of memory cells from a write booster cursor to long term data storage of the memory system.

Aspects of the process 300 may be implemented by one or more controllers, among other components. Additionally, or alternatively, aspects of the process 300 may be implemented as instructions stored in one or more memories (e.g., firmware stored in one or more memories coupled with memory system 110 or 210). For example, the instructions, if executed by one or more controllers (e.g., the memory system controller 115 or 215), may cause the one or more controllers (or a device or a system) to perform the operations of the process 300.

At 305, a determination may be made. For example, the memory system controller may determine whether a quantity of data stored to the memory system satisfies a first threshold value (e.g., exceeds, is greater than or equal to). In some examples, the quantity of data is associated with a logical saturation of the memory system. If the quantity of data does not satisfy the first threshold value, then the memory system may determine to conclude the operations of process 300.

At 310, a determination may be made. For example, if the quantity of data satisfies the first threshold value, then the memory system controller may determine whether a maintenance operation has begun at the memory system. A maintenance operation may be an example of an internal garbage collection (IGC) procedure. An IGC procedure may be invoked to allow blocks of the memory system to be erased and released as a free block for subsequent write operations. Garbage collection may refer to a set of media management operations that include, for example, selecting a block that contains valid and invalid data, selecting pages in the block that contain valid data, copying the valid data from the selected pages to new locations (e.g., free pages in another block), marking the data in the previously selected pages as invalid, and erasing the selected block. As a result, the quantity of blocks that have been erased may be increased such that more blocks are available to store subsequent data (e.g., data subsequently received from the host system 105 or 205). In some memory systems (e.g., NAND flash systems), data may not be overwritten directly. For instance, recently added data may be written to empty blocks, and data no longer in use by the memory system may be marked for deletion. In some instances, if a maintenance operation has not started, then the memory system controller may determine to conclude the operations of process 300.

At 315, a bit padding operation may be performed. For example, if the maintenance operation has started, then the memory system controller may begin the process of reallocating a virtual block associated with the write booster cursor (e.g., the block 235-c) for use in long term storage of data at the memory system. The techniques of process 300 may perform such a reallocation of the virtual block while maintaining RAIN parity of data stored to the virtual block. For example, the memory system controller may perform the bit padding operation to add additional bits of data (e.g., dummy bits) to fill a remaining portion of the currently open page line. In accordance with completing the bit padding operation, each page line of the virtual block that is currently storing data may be full.

At 320, an operation may be performed. For example, the memory system controller may perform a RAIN flush operation. Performing the RAIN flush operation may include identifying respective parity information associated with the virtual block that may be stored at the memory device. In response to identifying the parity information, the memory system controller may flush (e.g., write) the respective parity information stored at the memory device to a pageline of the virtual block associated with the location of the write booster cursor. As such, the memory system controller may preserve the RAIN parity information at the virtual block while refraining from performing a padding operation to the end of the virtual block.

At 325, an operation may be finalized. For example, the memory system controller may finalize the RAIN flush operation after the parity information stored at the memory device is transferred to the end of the virtual block (e.g., without additional padding bits to the end of the virtual block). In some examples, the RAIN flush operation may be a permanent RAIN flush, where after the parity information is transferred, the parity information is erased from the one or more first pages of the virtual block.

At 330, the write booster cursor may be closed. For example, the memory system controller may close the write booster cursor in response to allocating the virtual block for use in storing data during a normal mode of operation. In some examples, the virtual block may be operated as a TLC portion of memory (e.g., memory cells of the virtual block are each used to store three bits of information) or a QLC portion of memory (e.g., memory cells of the virtual block are used to store four bits of information).

At 335, the memory system controller may determine to end the operations associated with process 300. By operating in accordance with the techniques of process 300, the memory system controller may dynamically disable operations of the write booster cursor while preserving RAIN parity information stored at the virtual block associated with the write booster cursor. Such techniques may increase the data protection of information stored at the memory system while increasing the overall storage capacity of the memory system during instances of high logical saturation.

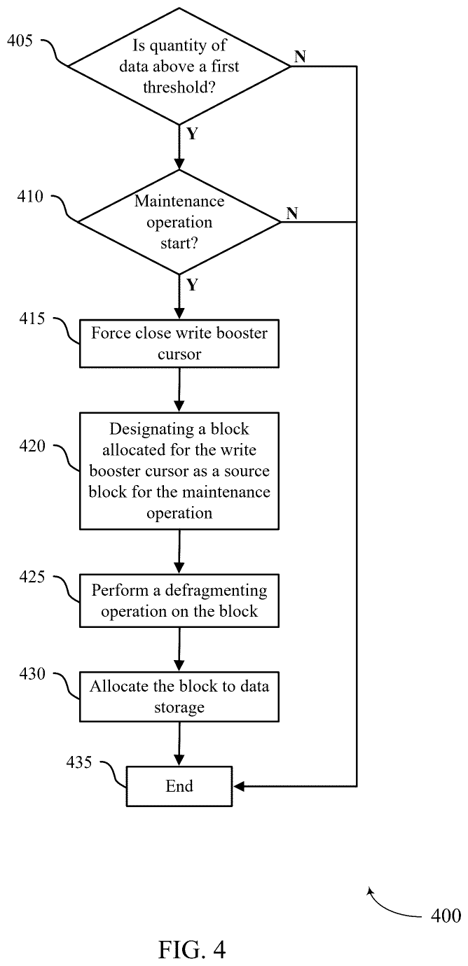

FIG. 4 shows an example of a process 400 that supports dynamic write booster disablement in accordance with examples as disclosed herein. In some examples, the process 400 may be implemented by one or more aspects of systems 100 and 200. For instance, the process 400 may be implemented by a memory system 110 or 210 described with reference to FIGS. 1 and 2. In some examples, the process 400 may correspond to one or more operations performed during maintenance operations of the memory system to dynamically allocate a block of memory cells from a write booster cursor to data storage of the memory system while reducing the time associated with performing the dynamic allocation.

Aspects of the process 400 may be implemented by one or more controllers, among other components. Additionally, or alternatively, aspects of the process 400 may be implemented as instructions stored in one or more memories (e.g., firmware stored in one or more memories coupled with memory system 110 or 210). For example, the instructions, if executed by one or more controllers (e.g., the memory system controller 115 or 215), may cause the one or more controllers (or a device or a system) to perform the operations of the process 400.

At 405, a determination may be made. For example, the memory system controller may determine whether a quantity of data stored to the memory system satisfies a first threshold value (e.g., exceeds, is greater than or equal to). In some examples, the quantity of data is associated with a logical saturation of the memory system. If the quantity of data is not above a first threshold value, then the memory system may determine to conclude the operations of the process 400.

At 410, a determination may be made. For example, the memory system controller may determine whether a maintenance operation has begun at the memory system. As described with reference to FIG. 3, a maintenance operation may be an example of an IGC procedure. If a maintenance operation has not started, then the memory system may determine to conclude the operations of the process 400.

At 415, the write booster cursor may be closed. For example, if the maintenance operation has started, then the memory system controller may force close the write booster cursor. As such, the memory system controller may begin the process of reallocating a virtual block associated with the write booster cursor (e.g., the block 235) for use in storing data at the memory system. The techniques of the process 400 may perform such a reallocation of the virtual block while reducing the time to perform said reallocation.

At 420, the virtual block may be designated as a source block. For instance, the memory system controller may designate the virtual block as the source block for the maintenance operation in response to determining the quantity of data stored to the memory system satisfies the first threshold value and in response to force closing the write booster cursor. By designating the virtual block as the source block, the memory system may start with the virtual block if performing the maintenance operation. As such, a time associated with reallocating the virtual block for use to store data may be reduced.

At 425, a defragmenting operation may be performed. For example, the memory system controller may defragment the virtual block in response to designating the virtual block as the source block. In some examples, defragmenting the virtual block may include transferring data stored to the virtual block to a second block of memory cells. Additionally, or alternatively, defragmentation may include the memory system controller rearranging data to consolidate the data stored to the memory system into pages that are physically contiguous. For instance, in accordance with the block being a virtual block, the data stored to the virtual block may be discontinuous. As such, if the memory system controller transfers the data stored to the virtual block to the second block, the memory system controller may write the data to the second block such that the data is physically contiguous.

At 430, the virtual block may be allocated for data storage. For example, the memory system controller may allocate virtual block for long term storage at the memory system in response to performing the defragmenting operation. In some examples, the memory system controller may allocate the virtual block for the TLC portion of memory (e.g., memory cells of the virtual block each store three bits of information) or for a QLC portion of memory (e.g., memory cells of the virtual block store four bits of information).

At 435, the memory system controller may determine to end the operations associated with the process 400. By operating in accordance with the techniques of process 400, the memory system controller may reduce the time associated with dynamically disabling operations of the write booster cursor. Such techniques may reduce the time to perform reallocation of the virtual block while increasing the overall storage capacity of the memory system during instances of high logical saturation.

FIG. 5 shows an example of a process 500 that supports dynamic write booster disablement in accordance with examples as disclosed herein. In some examples, the process 500 may be implemented by one or more aspects of systems 100 and 200. For instance, the process 500 may be implemented by a memory system 110 or 210 described with reference to FIGS. 1 and 2. In some examples, the process 500 may correspond to one or more operations performed after the operations of the process 300 or the process 400. For instance, the operations of the process 500 may include the memory system determining whether to reopen a second write booster cursor.

Aspects of the process 500 may be implemented by one or more controllers, among other components. Additionally, or alternatively, aspects of the process 500 may be implemented as instructions stored in one or more memories (e.g., firmware stored in one or more memories coupled with memory system 110 or 210). For example, the instructions, if executed by one or more controllers (e.g., the memory system controller 115 or 215), may cause the one or more controllers (or a device or a system) to perform the operations of the process 500.

At 505, a determination may be made. For example, the memory system controller may determine whether the write booster cursor is closed. In some examples, the memory system controller may close the write booster cursor in accordance with aspects of FIG. 3 (e.g., at 330) or in accordance with aspects of FIG. 4 (e.g., at 415). If the memory system controller determines that the write booster cursor is still open, then the memory system controller may determine to conclude the operations of the process 500.

At 510, the write booster mode may be disabled. For example, if the memory system controller determines that the write booster cursor has been closed, then the memory system controller may disable the operation of a write booster mode of the memory system after determining that the quantity of data satisfies the first threshold value and after closing the write booster cursor. In some examples, disabling the write booster mode may be associated with transitioning from enabled mode 250 to disabled mode 255, as described with reference to FIG. 2.

At 515, it may be determined if the maintenance operation is complete. For example, the memory system controller may determine whether the maintenance operation associated with reallocating the virtual block to stored data has completed. If the memory system controller determines that the maintenance operation is not complete, then the memory system controller may determine to conclude the operations of the process 500.

At 520, a determination may be made. For example, if the memory system controller determines that the maintenance operation is complete the memory system controller may determine if a write command associated with the write booster mode has been received. In some instances, the memory system controller may receive from a host system (e.g., the host system 105 or 205) a write command to write data using the write booster mode. In some examples, the memory system controller may receive such a write command after the disabling the operation of the write booster mode. In some cases, however, the memory system controller may receive a write command from the host system that is not associated with the write booster mode. In such cases, the memory system may determine to conclude operations of the process 500.

At 525, a determination may be made. For example, the memory system controller may determine whether the quantity of data stratifies a second threshold value (e.g., below, is less than or equal to). In some examples, the second threshold value may be lower than the first threshold value used to determine whether to close the write booster cursor. By configuring the second threshold value as lower than the first threshold value, the memory system controller may avoid frequently opening and closing subsequent write booster cursors if the quantity of data oscillates close to the first threshold value.

At 550, a write operation may be performed. For example, if the memory system controller determines that the quantity of data satisfies the second threshold value, then the memory system controller may write the data to a block of memory cells without using the write booster mode. In such examples, the memory system controller may write the data directly to a TLC portion or QLC portion of the memory system. After writing the data, the memory system may determine to conclude operations of the process 500.

At 530, a second write booster cursor may be opened. For example, if the memory system controller determines that the quantity of data satisfies the second threshold value, then the memory system controller may open the second write booster cursor in response to receiving the write command associated with using the write booster mode.

At 535, a second virtual block may be allocated to the second write booster cursor. For example, the memory system controller may allocate the second virtual block from being used as long term storage to the memory system to being associated with the second write booster cursor. In some examples, the memory system controller may use an SLC portion of memory as the second virtual block. After opening the second write booster cursor and allocating the second virtual block, the memory system controller may enable operation of the write booster mode.

At 540, the write command associated with the write booster mode may be performed. For example, the memory system controller may write, using the write booster mode, data associated with performing the write command to the second virtual block.

At 545, the memory system may determine to end the operations associated with the process 500. By dynamically allocating an SLC block (or multiple SLC blocks) for use in a write booster mode and for storing data, the memory system may increase the utilization of memory storage resources. As such, the memory system may increase data storage capacity during high levels of logical saturation while maintaining the performance increase associated with the write booster mode during lower levels of logical saturation.

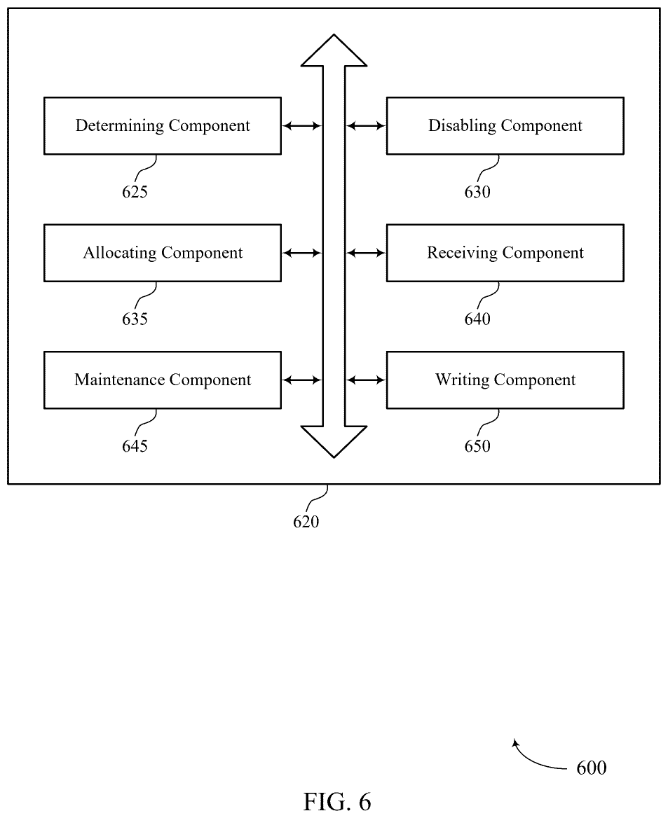

FIG. 6 shows a block diagram 600 of a memory system 620 that supports dynamic write booster disablement in accordance with examples as disclosed herein. The memory system 620 may be an example of aspects of a memory system as described with reference to FIGS. 1 through 5. The memory system 620, or various components thereof, may be an example of means for performing various aspects of dynamic write booster disablement as described herein. For example, the memory system 620 may include a determining component 625, a disabling component 630, an allocating component 635, a receiving component 640, a maintenance component 645, a writing component 650, or any combination thereof. Each of these components, or components of subcomponents thereof (e.g., one or more processors, one or more memories), may communicate, directly or indirectly, with one another (e.g., via one or more buses).

The determining component 625 may be configured as or otherwise support a means for determining whether a quantity of data stored to the memory system satisfies a first threshold value, where the quantity of data is associated with a logical saturation of the memory system, and where a block of memory cells of the memory system is allocated to a write booster cursor. The disabling component 630 may be configured as or otherwise support a means for disabling operation of a write booster mode of the memory system in response to determining that the quantity of data satisfies the first threshold value. The allocating component 635 may be configured as or otherwise support a means for allocating the block of memory cells of the write booster cursor to store data in response to disabling the operation of the write booster mode.

In some examples, the receiving component 640 may be configured as or otherwise support a means for receiving, after disabling the operation of the write booster mode, a write command to write data using the write booster mode. In some examples, the determining component 625 may be configured as or otherwise support a means for determining whether the quantity of data stored to the memory system satisfies a second threshold value in response to receiving the write command associated with the write booster mode.

In some examples, the allocating component 635 may be configured as or otherwise support a means for allocating a second block of memory cells to a second write booster cursor in response to determining that the quantity of data stored to the memory system satisfies the second threshold value, where the write booster mode is enabled in response to allocating the second block of memory cells to the second write booster cursor. In some examples, the writing component 650 may be configured as or otherwise support a means for writing, using the write booster mode, the data to the second block of memory cells in response to allocating the second block of memory cells to the second write booster cursor.

In some examples, the writing component 650 may be configured as or otherwise support a means for writing the data to a third block of memory cells without using the write booster mode in response to determining that the quantity of data stored to the memory system fails to satisfy the second threshold value.

In some examples, the second threshold value is different than the first threshold value.

In some examples, the maintenance component 645 may be configured as or otherwise support a means for performing, by the memory system, a maintenance operation, where allocating the block of memory cells for storing data at the memory system is in response to performing the maintenance operation.

In some examples, to support performing the maintenance operation, the maintenance component 645 may be configured as or otherwise support a means for identifying respective parity information stored to one or more first pages of the block of memory cells as allocated to the write booster cursor. In some examples, to support performing the maintenance operation, the maintenance component 645 may be configured as or otherwise support a means for transferring, from the one or more first pages of the block of memory cells, the respective parity information to one or more second pages of memory cells different than the one or more first pages of memory cells. In some examples, to support performing the maintenance operation, the maintenance component 645 may be configured as or otherwise support a means for erasing, in response to transferring the respective parity information, the block of memory cells, where disabling the operation of the write booster cursor is in response to erasing the block of memory cells allocated to the write booster cursor.

In some examples, the respective parity information is associated with a RAIN data protection scheme.

In some examples, to support performing the maintenance operation, the maintenance component 645 may be configured as or otherwise support a means for designating the block of memory cells as a source block for the maintenance operation in response to determining the quantity of data stored to the memory system satisfies the first threshold value. In some examples, to support performing the maintenance operation, the maintenance component 645 may be configured as or otherwise support a means for defragmenting the block of memory cells in response to designating the block of memory cells as the source block, where defragmenting the block of memory cells includes transferring data stored to the block of memory cells to a fourth block of memory cells, where disabling the operation of the write booster cursor is in response to defragmenting the block of memory cells.

In some examples, memory cells of the block of memory cells are each configured to store a single bit of data if allocated for the write booster cursor and are each configured to store multiple bits of data if allocated for storing data.

In some examples, the block of memory cells includes a virtual block.

In some examples, the described functionality of the memory system 620, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 620, or various components thereof, may be implemented at least in part by instructions (e.g., stored in memory, non-transitory computer-readable medium) executable by such at least one processor.

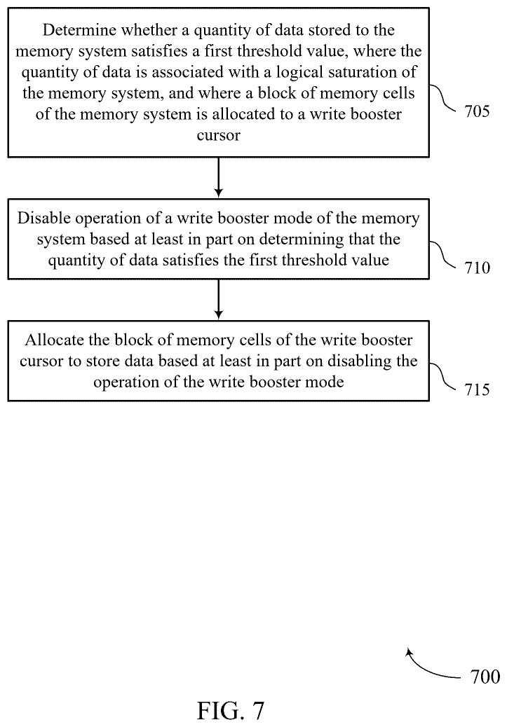

FIG. 7 shows a flowchart illustrating a method 700 that supports dynamic write booster disablement in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the memory system may perform aspects of the described functions using special-purpose hardware.

At 705, the method may include determining whether a quantity of data stored to the memory system satisfies a first threshold value, where the quantity of data is associated with a logical saturation of the memory system, and where a block of memory cells of the memory system is allocated to a write booster cursor. In some examples, aspects of the operations of 705 may be performed by a determining component 625 as described with reference to FIG. 6.

At 710, the method may include disabling operation of a write booster mode of the memory system in response to determining that the quantity of data satisfies the first threshold value. In some examples, aspects of the operations of 710 may be performed by a disabling component 630 as described with reference to FIG. 6.

At 715, the method may include allocating the block of memory cells of the write booster cursor to store data in response to disabling the operation of the write booster mode. In some examples, aspects of the operations of 715 may be performed by an allocating component 635 as described with reference to FIG. 6.

In some examples, an apparatus as described herein may perform a method or methods, such as the method 700. The apparatus may include operations, features, circuitry, logic, means, or instructions (e.g., a non-transitory computer-readable medium storing instructions executable by a processor), or any combination thereof for performing the following aspects as disclosed herein:

Aspect 1: A method, apparatus, or non-transitory computer-readable medium including operations, features, circuitry, logic, means, or instructions, or any combination thereof for determining whether a quantity of data stored to the memory system satisfies a first threshold value, where the quantity of data is associated with a logical saturation of the memory system, and where a block of memory cells of the memory system is allocated to a write booster cursor; disabling operation of a write booster mode of the memory system based at least in part on determining that the quantity of data satisfies the first threshold value; and allocating the block of memory cells of the write booster cursor to store data based at least in part on disabling the operation of the write booster mode.

Aspect 2: The method, apparatus, or non-transitory computer-readable medium of aspect 1, further including operations, features, circuitry, logic, means, or instructions, or any combination thereof for receiving, after disabling the operation of the write booster mode, a write command to write data using the write booster mode and determining whether the quantity of data stored to the memory system satisfies a second threshold value based at least in part on receiving the write command associated with the write booster mode.

Aspect 3: The method, apparatus, or non-transitory computer-readable medium of aspect 2, further including operations, features, circuitry, logic, means, or instructions, or any combination thereof for allocating a second block of memory cells to a second write booster cursor based at least in part on determining that the quantity of data stored to the memory system satisfies the second threshold value, where the write booster mode is enabled based at least in part on allocating the second block of memory cells to the second write booster cursor and writing, using the write booster mode, the data to the second block of memory cells based at least in part on allocating the second block of memory cells to the second write booster cursor.

Aspect 4: The method, apparatus, or non-transitory computer-readable medium of any of aspects 2 through 3, further including operations, features, circuitry, logic, means, or instructions, or any combination thereof for writing the data to a third block of memory cells without using the write booster mode based at least in part on determining that the quantity of data stored to the memory system fails to satisfy the second threshold value.

Aspect 5: The method, apparatus, or non-transitory computer-readable medium of any of aspects 2 through 4, where the second threshold value is different than the first threshold value.

Aspect 6: The method, apparatus, or non-transitory computer-readable medium of any of aspects 1 through 5, further including operations, features, circuitry, logic, means, or instructions, or any combination thereof for performing, by the memory system, a maintenance operation, where allocating the block of memory cells for storing data at the memory system is based at least in part on performing the maintenance operation.

Aspect 7: The method, apparatus, or non-transitory computer-readable medium of aspect 6, where performing the maintenance operation includes operations, features, circuitry, logic, means, or instructions, or any combination thereof for identifying respective parity information stored to one or more first pages of the block of memory cells as allocated to the write booster cursor; transferring, from the one or more first pages of the block of memory cells, the respective parity information to one or more second pages of memory cells different than the one or more first pages of memory cells; and erasing, based at least in part on transferring the respective parity information, the block of memory cells, where disabling the operation of the write booster cursor is based at least in part on erasing the block of memory cells allocated to the write booster cursor.

Aspect 8: The method, apparatus, or non-transitory computer-readable medium of aspect 7, where the respective parity information is associated with a RAIN data protection scheme.

Aspect 9: The method, apparatus, or non-transitory computer-readable medium of any of aspects 6 through 8, where performing the maintenance operation includes operations, features, circuitry, logic, means, or instructions, or any combination thereof for designating the block of memory cells as a source block for the maintenance operation based at least in part on determining the quantity of data stored to the memory system satisfies the first threshold value and defragmenting the block of memory cells based at least in part on designating the block of memory cells as the source block, where defragmenting the block of memory cells includes transferring data stored to the block of memory cells to a fourth block of memory cells, where disabling the operation of the write booster cursor is based at least in part on defragmenting the block of memory cells.

Aspect 10: The method, apparatus, or non-transitory computer-readable medium of any of aspects 1 through 9, where memory cells of the block of memory cells are each configured to store a single bit of data if allocated for the write booster cursor and are each configured to store multiple bits of data if allocated for storing data.

Aspect 11: The method, apparatus, or non-transitory computer-readable medium of any of aspects 1 through 10, where the block of memory cells includes a virtual block.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit in response to the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope in accordance with examples as disclosed herein. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
determine whether a quantity of data stored to the memory system satisfies a first threshold value, wherein the quantity of data is associated with a logical saturation of the memory system, and wherein a block of memory cells of the memory system is allocated to a write booster cursor;
disable operation of a write booster mode of the memory system based at least in part on determining that the quantity of data satisfies the first threshold value; and
allocate the block of memory cells of the write booster cursor to store data based at least in part on disabling the operation of the write booster mode.

2. The memory system of claim 1, wherein the processing circuitry is further configured to cause the memory system to:
receive, after disabling the operation of the write booster mode, a write command to write data using the write booster mode; and
determine whether the quantity of data stored to the memory system satisfies a second threshold value based at least in part on receiving the write command associated with the write booster mode.

3. The memory system of claim 2, wherein the processing circuitry is further configured to cause the memory system to:
allocate a second block of memory cells to a second write booster cursor based at least in part on determining that the quantity of data stored to the memory system satisfies the second threshold value, wherein the write booster mode is enabled based at least in part on allocating the second block of memory cells to the second write booster cursor; and
write, using the write booster mode, the data to the second block of memory cells based at least in part on allocating the second block of memory cells to the second write booster cursor.

4. The memory system of claim 2, wherein the processing circuitry is further configured to cause the memory system to:
write the data to a third block of memory cells without using the write booster mode based at least in part on determining that the quantity of data stored to the memory system fails to satisfy the second threshold value.

5. The memory system of claim 1, wherein the processing circuitry is further configured to cause the memory system to:
perform, by the memory system, a maintenance operation, wherein allocating the block of memory cells for storing data at the memory system is based at least in part on performing the maintenance operation.

6. The memory system of claim 5, wherein performing the maintenance operation comprises the processing circuitry configured to cause the memory system to:
identify respective parity information stored to one or more first pages of the block of memory cells as allocated to the write booster cursor;
transfer, from the one or more first pages of the block of memory cells, the respective parity information to one or more second pages of memory cells different than the one or more first pages of memory cells; and
erase, based at least in part on transferring the respective parity information, the block of memory cells, wherein disabling the operation of the write booster cursor is based at least in part on erasing the block of memory cells allocated to the write booster cursor.

7. The memory system of claim 6, wherein the respective parity information is associated with a redundant array of independent NAND (RAIN) data protection scheme.

8. The memory system of claim 5, wherein performing the maintenance operation comprises the processing circuitry configured to cause the memory system to:
designate the block of memory cells as a source block for the maintenance operation based at least in part on determining the quantity of data stored to the memory system satisfies the first threshold value; and
defragment the block of memory cells based at least in part on designating the block of memory cells as the source block, wherein defragmenting the block of memory cells comprises transferring data stored to the block of memory cells to a fourth block of memory cells, wherein disabling the operation of the write booster cursor is based at least in part on defragmenting the block of memory cells.

9. The memory system of claim 1, wherein memory cells of the block of memory cells are each configured to store a single bit of data based at least in part on being allocated for the write booster cursor and are each configured to store multiple bits of data based at least in part on being allocated for storing data.

10. The memory system of claim 1, wherein the block of memory cells comprises a virtual block.

11. A non-transitory computer-readable medium storing code comprising instructions which, when executed by one or more processors of a memory system, cause the memory system to:
determine whether a quantity of data stored to the memory system satisfies a first threshold value, wherein the quantity of data is associated with a logical saturation of the memory system, and wherein a block of memory cells of the memory system is allocated to a write booster cursor;
disable operation of a write booster mode of the memory system based at least in part on determining that the quantity of data satisfies the first threshold value; and
allocate the block of memory cells of the write booster cursor to store data based at least in part on disabling the operation of the write booster mode.

12. The non-transitory computer-readable medium of claim 11, wherein the instructions, when executed by the one or more processors of the memory system, further cause the memory system to:
receive, after disabling the operation of the write booster mode, a write command to write data using the write booster mode; and
determine whether the quantity of data stored to the memory system satisfies a second threshold value based at least in part on receiving the write command associated with the write booster mode.

13. The non-transitory computer-readable medium of claim 12, wherein the instructions, when executed by the one or more processors of the memory system, further cause the memory system to:
allocate a second block of memory cells to a second write booster cursor based at least in part on determining that the quantity of data stored to the memory system satisfies the second threshold value, wherein the write booster mode is enabled based at least in part on allocating the second block of memory cells to the second write booster cursor; and
write, using the write booster mode, the data to the second block of memory cells based at least in part on allocating the second block of memory cells to the second write booster cursor.

14. The non-transitory computer-readable medium of claim 12, wherein the instructions, when executed by the one or more processors of the memory system, further cause the memory system to:
write the data to a third block of memory cells without using the write booster mode based at least in part on determining that the quantity of data stored to the memory system fails to satisfy the second threshold value.

15. The non-transitory computer-readable medium of claim 11, wherein the instructions, when executed by the one or more processors of the memory system, further cause the memory system to:
perform, by the memory system, a maintenance operation, wherein allocating the block of memory cells for storing data at the memory system is based at least in part on performing the maintenance operation.

16. The non-transitory computer-readable medium of claim 15, wherein the instructions to perform the maintenance operation, when executed by the one or more processors of the memory system, further cause the memory system to:
identify respective parity information stored to one or more first pages of the block of memory cells as allocated to the write booster cursor;
transfer, from the one or more first pages of the block of memory cells, the respective parity information to one or more second pages of memory cells different than the one or more first pages of memory cells; and
erase, based at least in part on transferring the respective parity information, the block of memory cells, wherein disabling the operation of the write booster cursor is based at least in part on erasing the block of memory cells allocated to the write booster cursor.

17. The non-transitory computer-readable medium of claim 16, wherein the respective parity information is associated with a redundant array of independent NAND (RAIN) data protection scheme.

18. The non-transitory computer-readable medium of claim 15, wherein the instructions to perform the maintenance operation, when executed by the one or more processors of the memory system, further cause the memory system to:
designate the block of memory cells as a source block for the maintenance operation based at least in part on determining the quantity of data stored to the memory system satisfies the first threshold value; and
defragment the block of memory cells based at least in part on designating the block of memory cells as the source block, wherein defragmenting the block of memory cells comprises transferring data stored to the block of memory cells to a fourth block of memory cells, wherein disabling the operation of the write booster cursor is based at least in part on defragmenting the block of memory cells.

19. The non-transitory computer-readable medium of claim 11, wherein memory cells of the block of memory cells are each configured to store a single bit of data based at least in part on being allocated for the write booster cursor and are each configured to store multiple bits of data based at least in part on being allocated for storing data.

20. The non-transitory computer-readable medium of claim 11, wherein the block of memory cells comprises a virtual block.

21. A method by a memory system, comprising:
determining whether a quantity of data stored to the memory system satisfies a first threshold value, wherein the quantity of data is associated with a logical saturation of the memory system, and wherein a block of memory cells of the memory system is allocated to a write booster cursor;
disabling operation of a write booster mode of the memory system based at least in part on determining that the quantity of data satisfies the first threshold value; and
allocating the block of memory cells of the write booster cursor to store data based at least in part on disabling the operation of the write booster mode.

22. The method of claim 21, further comprising:
receiving, after disabling the operation of the write booster mode, a write command to write data using the write booster mode; and
determining whether the quantity of data stored to the memory system satisfies a second threshold value based at least in part on receiving the write command associated with the write booster mode.

23. The method of claim 22, further comprising:
allocating a second block of memory cells to a second write booster cursor based at least in part on determining that the quantity of data stored to the memory system satisfies the second threshold value, wherein the write booster mode is enabled based at least in part on allocating the second block of memory cells to the second write booster cursor; and
writing, using the write booster mode, the data to the second block of memory cells based at least in part on allocating the second block of memory cells to the second write booster cursor.

24. The method of claim 22, further comprising:
writing the data to a third block of memory cells without using the write booster mode based at least in part on determining that the quantity of data stored to the memory system fails to satisfy the second threshold value.

25. The method of claim 21, further comprising:
performing, by the memory system, a maintenance operation, wherein allocating the block of memory cells for storing data at the memory system is based at least in part on performing the maintenance operation.
